(19) United States
(12) Patent Application Publication
(10) Pub. No.: US 2026/0173668 A1
(43) Pub. Date: Jun. 18, 2026

(54) DISPLAY DEVICE HAVING OPENING IN PERIPHERAL AREA AND ELECTRONIC DEVICE INCLUDING THE SAME

(71) Applicant: Samsung Display Co., LTD., Yongin-si (KR)

(72) Inventors: GIJUNG LEE, Yongin-si (KR); JAEEUN YU, Yongin-si (KR); JU-YEON SEO, Yongin-si (KR); DONG-YOON SO, Yongin-si (KR); SOODONG SON, Yongin-si (KR)

(21) Appl. No.: 19/243,796

(22) Filed: Jun. 20, 2025

(30) Foreign Application Priority Data
Dec. 18, 2024 (KR) 10-2024-0189637

(51) Int. Cl. H10K 59/124; H10K 59/40

(52) U.S. Cl. CPC H10K 59/124; H10K 59/40

(57) ABSTRACT

A display device including a display area, a sub-area and a bending area, an inorganic insulating layer in the display area and sub-area, an organic layer in the display area and sub-area and in which an opening is defined in the sub-area, the opening exposing the inorganic insulating layer and defined by a first side surface and a second side surface which is further from the bending area than the first side surface, and a touch sensor layer including a first touch electrode overlapping the display area, a touch inorganic insulating layer including a first portion covering the first touch electrode, in the display area, and a second portion covering the second side surface and not overlapping the first side surface, in the sub-area, a second touch electrode in the display area, and a touch protection layer covering the second touch electrode.

This application claims priority to Korean Patent Application No. 10-2024-0189637 filed on Dec. 18, 2024, and all the benefits accruing therefrom under 35 U.S.C. § 119, the entire contents of which are hereby incorporated by reference.

### BACKGROUND

### 1. Field

Embodiments provide a display device, and an electronic device including the same. More particularly, embodiments relate to the display device which provides visual information, and the electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

### SUMMARY

Embodiments provide a display device with improved reliability.

Embodiments provide an electronic device including the display device.

A display device according to embodiments of the present disclosure includes a substrate including a display area in which a plurality of pixels are arranged and a peripheral area surrounding the display area and including a sub-area and a bending area positioned between the display area and the sub-area, an inorganic insulating layer on the substrate, an organic layer in the sub-area on the inorganic insulating layer, defining an opening, the opening having a first side surface adjacent to the bending area and a second side surface opposite to the first side surface and exposing at least a portion of the inorganic insulating layer, and a touch sensor layer on the pixels and including a first touch electrode overlapping the display area, a touch insulating layer covering the first touch electrode, including an inorganic material, extending from the display area to at least a portion of the sub-area, and covering the second side surface without overlapping the first side surface of the opening in the sub-area in a plan view, a second touch electrode in the display area on the touch insulating layer, and a touch protection layer covering the second touch electrode.

In an embodiment, the touch insulating layer may directly contact at least a portion of an upper surface of the inorganic insulating layer and the second side surface of the opening in the sub-area.

In an embodiment, the organic layer may include a first organic layer defining a first opening exposing at least a portion of the inorganic insulating layer and a second organic layer on the first organic layer and defining a second opening having a width smaller than a width of the first opening and overlapping the first opening in the plan view. The first side surface may include a first-first side surface and a first-second side surface of the first opening and the second side surface may include a second-first side surface and a second-second side surface of the second opening, and the touch insulating layer may directly contact the second-second side surface of the second opening.

In an embodiment, the display device may further include a first via insulating layer in the display area on the inorganic insulating layer, a second via insulating layer in the display area on the first via insulating layer, a pixel electrode on the second via insulating layer, and a pixel defining layer defining a pixel opening exposing at least a portion of the pixel electrode. The first organic layer and the second via insulating layer may include a same material, and the second organic layer and the pixel defining layer may include a same material.

In an embodiment, the touch protection layer may extend from the display area to at least a portion of the sub-area.

In an embodiment, the touch protection layer may include an organic material, and the touch protection layer may cover the first side surface and the second side surface of the opening in the sub-area.

In an embodiment, the display device may further include a black matrix in the display area on the touch sensor layer, a color filter in the display area on the touch sensor layer and black matrix, and an overcoat layer covering the black matrix and the color filter, including an organic material, and extending from the display area to at least portion of the sub-area.

In an embodiment, the touch protection layer may include an inorganic material.

In an embodiment, the touch protection layer may cover the first side surface and the second side surface of the opening in the sub-area.

In an embodiment, the touch protection layer may cover the second side surface of the opening without overlapping the first side surface of the opening in the plan view in the sub-area.

In an embodiment, the overcoat layer may cover the first side surface and the second side surface of the opening.

In an embodiment, the display device may further include a driving voltage supply line in the sub-area, including a body portion connected to a circuit board and branch portions branching from the body portion, and which provides a driving voltage to the plurality of pixels. The opening of the organic layer may be positioned between the branch portions of the driving voltage supply line in the plan view.

In an embodiment, the touch insulating layer may include silicon, such as a silicon compound.

In an embodiment, the substrate may be a flexible polymer substrate.

An electronic device according to embodiments of the present disclosure includes a display device and a processor which controls the display device. The display device includes a substrate including a display area in which a plurality of pixels are arranged and a peripheral area surrounding the display area and including a sub-area and a bending area positioned between the display area and the sub-area, an inorganic insulating layer on the substrate, an organic layer in the sub-area on the inorganic insulating layer, defining an opening, the opening having a first side surface adjacent to the bending area and a second side surface opposite to the first side surface and exposing at least a portion of the inorganic insulating layer, and a touch sensor layer on the pixels and including a first touch electrode overlapping the display area, a touch insulating layer covering the first touch electrode, including an inorganic material, extending from the display area to at least a portion of the sub-area, and covering the second side surface without overlapping the first side surface of the opening in the sub-area in a plan view, a second touch electrode in the display area on the touch insulating layer, and a touch protection layer covering the second touch electrode.

In an embodiment, the touch insulating layer may directly contact at least a portion of an upper surface of the inorganic insulating layer and the second side surface of the opening in the sub-area.

In an embodiment, the organic layer may include a first organic layer defining a first opening exposing at least a portion of the inorganic insulating layer, and a second organic layer on the first organic layer and defining a second opening having a width smaller than a width of the first opening and overlapping the first opening in the plan view. The first side surface may include a first-first side surface and a first-second side surface of the first opening and the second side surface may include a second-first side surface and a second-second side surface of the second opening, and the touch insulating layer may directly contact the second-second side surface of the second opening.

In an embodiment, the display device may further include a first via insulating layer in the display area on the inorganic insulating layer, a second via insulating layer in the display area on the first via insulating layer, a pixel electrode on the second via insulating layer, and a pixel defining layer defining a pixel opening exposing at least a portion of the pixel electrode. The first organic layer and the second via insulating layer may include a same material, and the second organic layer and the pixel defining layer may include a same material.

In an embodiment, the touch protection layer may extend from the display area to at least a portion of the sub-area and includes an organic material, and the touch protection layer may cover the first side surface and the second side surface of the opening in the sub-area.

In an embodiment, the touch protection layer may extend from the display area to at least a portion of the sub-area and includes an inorganic material, and the touch protection layer may cover the second side surface of the opening in the sub-area.

In a display device according to embodiments of the present disclosure, an organic layer disposed in a sub-area on an inorganic insulating layer may define an opening having a first side surface adjacent to a bending area and a second side surface opposite to the first side surface, and a touch insulating layer may cover the second side surface without overlapping the first side in a plan view in the sub-area. Accordingly, oxidation of the touch insulating layer due to moisture penetrating into the organic layer adjacent to the bending area may not occur, and outgassing bubbles may not occur. In this case, cracks in the touch insulating layer and corrosion of a signal line such as a data line may be prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a perspective view illustrating the display device of FIG. 1 which is bent.

FIG. 3 is a cross-sectional view schematically illustrating the display device of FIG. 1.

FIG. 4 is a circuit diagram illustrating a circuit structure of a pixel of FIG. 1.

FIG. 5 is a plan view illustrating a first pad area of FIG. 1.

FIG. 6 is an enlarged cross-sectional view illustrating an example of a driving integrated circuit bonded on a plurality of pads of FIG. 5.

FIG. 7 is a cross-sectional view taken along line I-I′ of FIG. 1.

FIG. 8 is an enlarged plan view illustrating of a portion of a bending area and a sub-area of the display device of FIG. 1.

FIGS. 9A and 9B are cross-sectional views taken along lines II-II′ and III-III′ of FIG. 8, respectively.

FIG. 10 is a plan view illustrating a display device according to an embodiment of the present disclosure.

FIGS. 11 and 12 are cross-sectional views illustrating the display device of FIG. 10 which is folded.

FIG. 13 is a cross-sectional view taken along line IV-IV′ of FIG. 10.

FIG. 14 is an enlarged plan view illustrating a portion of a bending area and a sub-area of the display device of FIG. 10.

FIGS. 15A and 15B are cross-sectional views taken along lines V-V′ and the VI-VI′ of FIG. 14, respectively.

FIGS. 16A and 16B are cross-sectional views taken along lines V-V′ and the VI-VI′ of FIG. 14, respectively.

FIG. 17 is a block diagram illustrating an electronic device including a display device according to embodiments of the present disclosure.

FIG. 18 is a view illustrating an example of the electronic device of FIG. 17 being implemented as a television.

FIG. 19 is a view illustrating an example of the electronic device of FIG. 17 being implemented as a smartphone.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “first-first,” “first-second,” “second,” “second-first,” “second-second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device DD and an electronic device ED including the same according to embodiments of the present disclosure will be explained in detail with reference to the accompanying drawings.

The same reference numerals are used for the same components in the drawings, and redundant descriptions of the same components will be omitted.

In this specification, a plane may be defined as a first direction DR1 and a second direction DR2 which intersects the first direction DR1. For example, the first direction DR1 may be perpendicular to the second direction DR2. In addition, a third direction DR3 may be perpendicular to the plane. A thickness of the display device DD and various components or layers thereof may be defined along the third direction DR3 (e.g., a thickness direction).

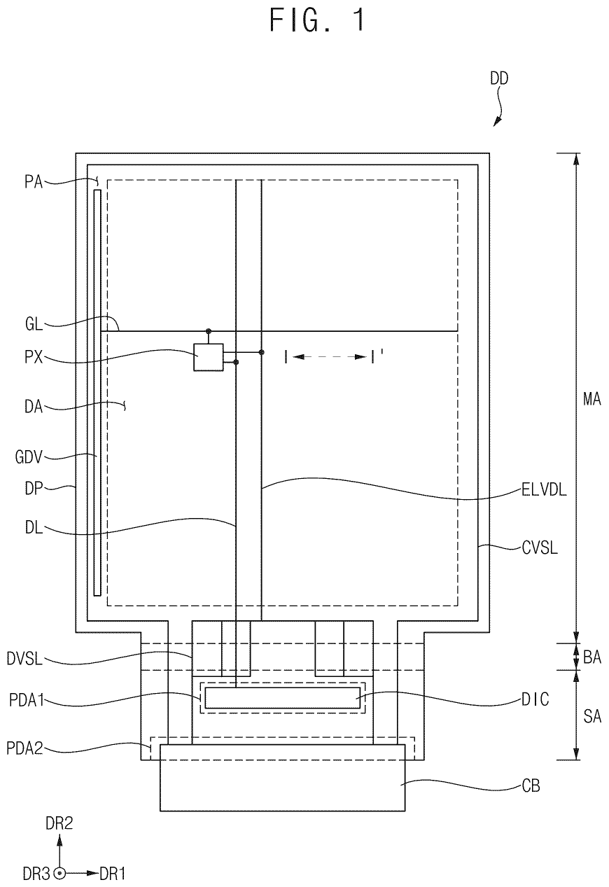

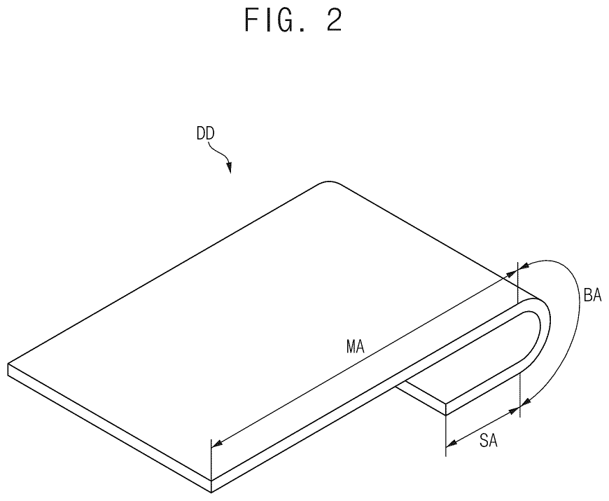

FIG. 1 is a plan view illustrating a display device DD according to an embodiment of the present disclosure. FIG. 2 is a view illustrating a bent shape of the display device DD of FIG. 1, that is, the display device DD which is bent. The display device DD may be considered an electronic apparatus itself and/or may be included in an electronic device ED.

Referring to FIGS. 1 and 2, a display device DD according to an embodiment of the invention may include a display panel DP, a gate driver GDV, a driving integrated circuit DIC, and a circuit board CB.

The display device DD may have a rectangular planar shape (e.g., a rectangular planar shape with rounded corners, right angle corners, etc.). However, the embodiments of the present disclosure are not necessarily limited thereto, and the display device DD may have various planar shapes.

The display panel DP may include a display area DA and a peripheral area PA. The display area DA may be an area (e.g., a planar area) which generates light and/or may display an image by controlling the transmittance of light provided from an external light source. The peripheral area PA may be an area which does not display an image, does not emit light, etc. The peripheral area PA may be positioned adjacent to the display area DA, such as being around the display area DA. For example, the peripheral area PA may entirely surround the display area DA. The peripheral area PA may be otherwise referred to as a non-display area.

The display panel DP may include a pixel PX provided in plural including a plurality of pixels PX arranged in the display area DA. The plurality of pixels PX may be arranged in a matrix form along the first direction DR1 and the second direction DR2. However, the embodiments of the present disclosure are not necessarily limited thereto, and the plurality of pixels PX may be arranged in various forms. Within the Figures and the text of the disclosure, a reference number indicating a singular form of an element may also be used to reference a plurality of the element.

Each of the plurality of pixels PX may include a driving element (e.g., a driving transistor) which generates a driving current (e.g., electrical current), and a light-emitting element LED (e.g., an organic light-emitting diode) which is electrically connected to the driving element and generates light based on the driving current. Accordingly, each of the pixels PX may emit light according to the driving current. As the pixels PX emit light, the display area DA may display an image.

In the peripheral area PA, drivers for driving the plurality of pixels PX may be disposed. For example, the gate driver GDV and the driving integrated circuit DIC may be disposed in the peripheral area PA. Such elements may be variously connected to the pixels PX.

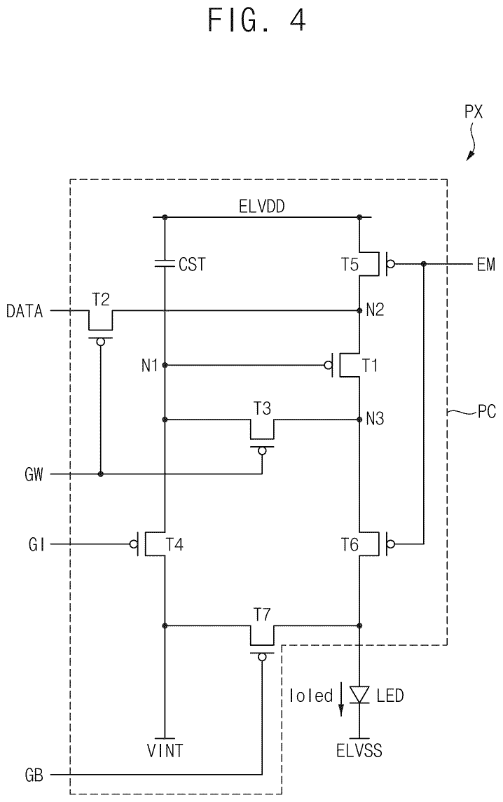

The gate driver GDV may be disposed in the peripheral area PA adjacent to the left and/or right edges of the display area DA. The gate driver GDV may receive a control signal from the circuit board CB and generate a gate signal based on the control signal. For example, the gate signal may be at least one of gate signals GW, GI, and GB and an emission control signal EM of FIG. 4.

The display panel DP may further include lines (e.g., signal lines, conductive lines, etc.) arranged in the display area DA and connected to the plurality of pixels PX. For example, the lines may include a data line DL, a gate signal line GL, and a driving voltage line ELVDL.

In addition, the display panel DP may further include a control signal line (not shown) disposed in the peripheral area PA and connected to the gate driver GDV, a driving voltage supply line DVSL connected to the circuit board CB, and a common voltage supply line CVSL connected to the circuit board CB.

The gate signal line GL may be electrically connected to the gate driver GDV and extend in the first direction DR1. The gate signal line GL may receive the gate signal from the gate driver GDV and provide the gate signal to the plurality of pixels PX. The control signal line may be electrically connected to the circuit board CB, receives the control signal from the circuit board CB, and provide the control signal to the gate driver GDV.

The data line DL may be electrically connected to the driving integrated circuit DIC and extend in the second direction DR2. The data line DL may receive a data voltage (e.g., a data voltage DATA of FIG. 4) from the driving integrated circuit DIC. The data line DL may provide the data voltage to the plurality of pixels PX.

The driving voltage line ELVDL may extend along the second direction DR2. The driving voltage line ELVDL may provide a driving voltage (e.g., a driving voltage ELVDD of FIG. 4) to the plurality of pixels PX.

The driving voltage supply line DVSL may be disposed between the driving integrated circuit DIC and the display area DA in the plan view. The driving voltage supply line DVSL may be electrically connected to the circuit board CB. The driving voltage supply line DVSL may receive the driving voltage from the circuit board CB and provide the driving voltage to the driving voltage line ELVDL.

The common voltage supply line CVSL may extend along an edge of the peripheral area PA. That is, the common voltage supply line CVSL may be disposed to surround at least a portion of the display area DA. For example, the common voltage supply line CVSL may include a first portion extending in the second direction DR2 and disposed at a left edge of the peripheral area PA, a second portion extending from the first portion in the first direction DR1 and disposed at an upper edge of the peripheral area PA, and a third portion extending from the second portion in the second direction DR2 and disposed at a right edge of the peripheral area PA.

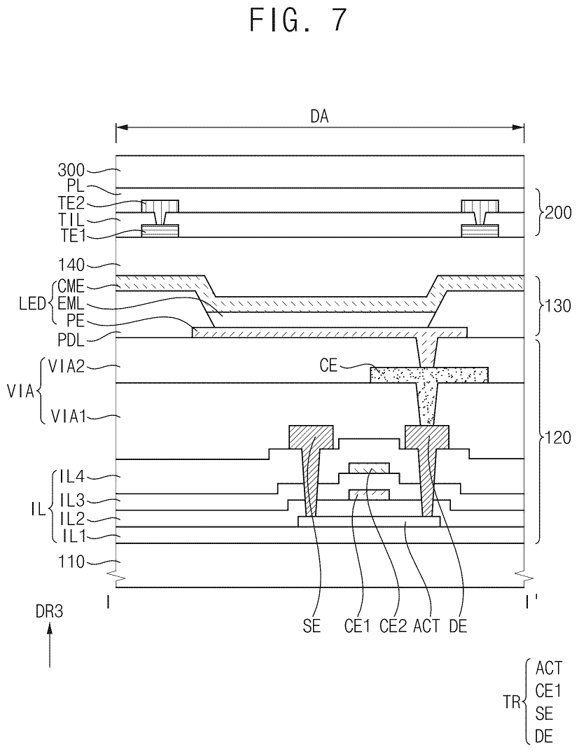

The common voltage supply line CVSL may be electrically connected to the circuit board CB. Specifically, the first portion and the third portion of the common voltage supply line CVSL may be directly connected to the circuit board CB. The common voltage supply line CVSL may receive a common voltage (e.g., a common voltage ELVSS of FIG. 4) from the circuit board CB and provide the common voltage to a common electrode (e.g., a common electrode CME of FIG. 7).

The peripheral area PA may include a bending area BA and a sub-area SA. The sub-area SA may be positioned at one side of the display area DA. Specifically, the sub-area SA may be positioned spaced apart from one side of the display area DA in a direction opposite to the second direction DR2.

The sub-area SA may include a first pad area PDA1 and a second pad area PDA2 spaced apart from each other in the second direction DR2. The first pad area PDA1 may be positioned between the bending area BA and the second pad area PDA2 in the plan view. The second pad area PDA2 may be positioned at an end of the sub-area SA. The second pad area PDA2 may have an edge which corresponds to or is aligned with an outer edge of a substrate 110 of the display panel DP.

The bending area BA may be positioned between the display area DA and the sub-area SA in the plan view. As illustrated in FIG. 2, the bending area BA may be bent based on a bending axis extending in the first direction DR1. In this case, the display device DD which is bent may include the sub-area SA disposed to overlap a main area MA of the display panel DP. The main area may be defined as a portion of the display area DA and the peripheral area PA, in the plan view. That is, in case that the display panel is bent at the bending area BA, the sub-area SA of the display panel DP may be positioned under the main area MA along the thickness direction. The display device DD may be provided in a shape in which the bending area BA is bent based on the bending axis.

The driving integrated circuit DIC may be bonded to the display panel DP at the first pad area PDA1 thereof. Accordingly, the driving integrated circuit DIC may be electrically connected to the display panel DP at the first pad area PDA1. For example, the driving integrated circuit DIC may be bonded to the first pad area PDA1 on the display panel DP by a thermal compression method.

The driving integrated circuit DIC may convert a digital data signal among the driving signals into an analog data signal (e.g., a data voltage) and provide the analog data signal to the plurality of pixels PX. For example, the driving integrated circuit DIC may be a data driver.

The circuit board CB may be bonded to the display panel DP at the second pad area PDA2 thereof. Specifically, one end (e.g., a first end) of the circuit board CB which is closest to the display area DA may be bonded to the second pad area PDA2. Accordingly, the circuit board CB may be electrically connected to the display panel DP at the second pad area PDA2. The other end of the circuit board CB (e.g., a second end opposite to the first end) may be electrically connected to an external device. A signal (e.g., the control signal), a voltage (e.g., the driving voltage, the common voltage, and the like), and the like generated from the external device which is outside the display device DD may be provided to the driving integrated circuit DIC and the gate driver GDV, through the circuit board CB.

For example, the circuit board CB may be a flexible printed circuit board (FPCB), a printed circuit board (PCB), or a flexible flat cable (FFC).

In FIG. 1, the driving integrated circuit DIC is illustrated as being disposed in a COP (chip on plastic) manner or a COG (chip on glass) manner, but embodiments of the invention are not necessarily limited thereto. For example, the driving integrated circuit DIC may be disposed in a COF (chip on film) manner.

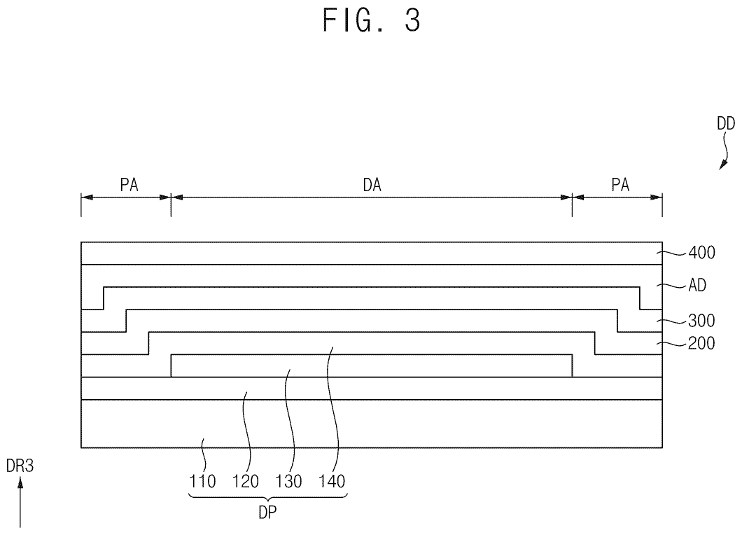

FIG. 3 is a cross-sectional view schematically illustrating the display device DD of FIG. 1.

Referring to FIG. 3, the display device DD may further include a touch sensor layer 200 as a touch-sensing layer, an anti-reflection layer 300, an adhesive layer AD, and a window member 400 as a window layer, which are sequentially disposed along the third direction DR3 on the display panel DP.

Here, the display panel DP may include a substrate 110, a pixel circuit layer 120 as a circuit (or transistor) layer disposed on the substrate 110, a light-emitting element layer 130 as a display element layer disposed on the pixel circuit layer 120, and an encapsulation layer 140 disposed on the light-emitting element layer 130.

The substrate 110 may be a glass substrate, a metal substrate, or a polymer substrate. In an embodiment, the substrate 110 may be a flexible polymer substrate. However, the embodiments of the present disclosure are not necessarily limited thereto, and the substrate 110 may be an inorganic layer, an organic layer, or a composite material layer.

The above pixel circuit layer 120 may include an insulating layer, a semiconductor element (e.g., a transistor), a conductive layer, a signal line, and the like.

The light-emitting element layer 130 may include a light-emitting element which generates light. For example, the light-emitting element may include an organic light-emitting material, an inorganic light-emitting material, an organic-inorganic light-emitting material, a quantum dot, a micro light-emitting diode or device (LED), or a nano LED.

The encapsulation layer 140 may protect the light-emitting element layer 130 from foreign substances such as moisture, oxygen, and the like. For example, the encapsulation layer 140 may include at least one inorganic layer and at least one organic layer. In one embodiment, the encapsulation layer 140 may have a laminated structure of a first inorganic layer, an organic layer, and a second inorganic layer in order.

The touch sensor layer 200 may be disposed on the display panel DP. The touch sensor layer 200 may detect an external input applied from the outside (e.g., outside of the display panel DP and/or outside of the display device DD). The external input may be pressure, hovering in proximity, light, heat, etc. the external input may be applied by an input tool such as a body part of a user, a pen, etc. For example, the touch sensor layer 200 may be directly formed (or provided) on the display panel DP such as through a continuous process. Alternatively, the touch sensor layer 200 may be manufactured through a separate process and then attached to the display panel DP with a separate (or intervening) member.

The anti-reflection layer 300 may be disposed on the touch sensor layer 200. The anti-reflection layer 300 may reduce the reflectivity of external light incident from the outside of the display device DD. The anti-reflection layer 300 may include a phase retarder and a polarizer. The phase retarder may be a film type or a liquid crystal coating type, and may include a λ/2 phase retarder and/or a λ/4 phase retarder. The polarizer may be a film type or a liquid crystal coating type.

Alternatively, the anti-reflection layer 300 may be formed on the touch sensor layer 200 such as through a continuous process. In this case, the anti-reflection layer 300 may include color filters which selectively transmit light of a specific color and a black matrix which is disposed between the color filters.

The window member 400 may be attached to the anti-reflection layer 300 through the adhesive layer AD. The window member 400 may include a base film including a glass film or a synthetic resin film. The window member 400 may further include an anti-reflection layer or an anti-fingerprint layer.

FIG. 4 is a circuit diagram illustrating a circuit structure of a pixel PX of FIG. 1.

Referring to FIG. 4, a pixel PX may include a pixel driving circuit part PC and a light-emitting element LED which is electrically connected to the pixel driving circuit part PC. The pixel driving circuit part PC may generate a driving current Ioled, and the light-emitting element LED may generate light based on the driving current Ioled.

For example, the pixel driving circuit part PC may include a transistor provided in plural including a first transistor T1, a second transistor T2, a third transistor T3, a fourth transistor T4, a fifth transistor T5, a sixth transistor T6, a seventh transistor T7, and a storage capacitor Cst.

In an embodiment, the first transistor T1, the second transistor T2, the third transistor T3, the fourth transistor T4, the fifth transistor T5, the sixth transistor T6, and the seventh transistor T7 may be PMOS transistors. However, embodiments of the present disclosure are not necessarily limited thereto, and the first transistor T1, the second transistor T2, the fifth transistor T5, the sixth transistor T6, and the seventh transistor T7 may be PMOS transistors, and the third transistor T3 and the fourth transistor T4 may be NMOS transistors.

In case that the above pixel driving circuit part PC includes an NMOS transistor and a PMOS transistor, an active pattern of the NMOS transistor may include an oxide semiconductor, and an active pattern of the PMOS transistor may include a silicon semiconductor. However, the embodiments of the present disclosure are not necessarily limited thereto, and the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current Ioled to the light-emitting element LED. The first transistor T1 may be referred to as a driving transistor.

The second transistor T2 may include a gate electrode, a first electrode, and a second electrode. The first gate signal GW may be applied to the gate electrode of the second transistor T2. The data voltage DATA may be applied to the first electrode of the second transistor T2. The second electrode of the second transistor T2 may be connected to the second node N2.

The second transistor T2 may be turned on or off in response to the first gate signal GW. For example, in case that the first gate signal GW has an activated level, the second transistor T2 may be turned on. In this case, the second transistor T2 may provide the data voltage DATA to the second node N2. Conversely, in case that the first gate signal GW has a deactivated level, the second transistor T2 may be turned off. In this case, the second transistor T2 may block the supply of the data voltage DATA.

The third transistor T3 may include a gate electrode, a first electrode, and a second electrode. The first gate signal GW may be applied to the gate electrode of the third transistor T3. The first electrode of the third transistor T3 may be connected to the third node N3. The second electrode of the third transistor T3 may be connected between the first node N1 and the second electrode of the fourth transistor T4.

The fourth transistor T4 may include a gate electrode, a first electrode, and a second electrode. The second gate signal GI may be applied to the gate electrode of the fourth transistor T4. An initialization voltage VINT may be applied to the first electrode of the fourth transistor T4. The second electrode of the fourth transistor T4 may be connected to the second electrode of the third transistor T3.

The fourth transistor T4 may be turned on or off in response to the second gate signal GI. For example, in case that the second gate signal GI has an activated level, the fourth transistor T4 may be turned on. In this case, the fourth transistor T4 may provide the initialization voltage VINT to the second electrode of the third transistor T3. Conversely, in case that the second gate signal GI has a deactivated level, the fourth transistor T4 may block the supply of the initialization voltage VINT.

The fifth transistor T5 may include a gate electrode, a first electrode, and a second electrode. The emission control signal EM may be applied to the gate electrode of the fifth transistor T5. The driving voltage ELVDD may be applied to the first electrode of the fifth transistor T5. The second electrode of the fifth transistor T5 may be connected to the second node N2.

The sixth transistor T6 may include a gate electrode, a first electrode, and a second electrode. The emission control signal EM may be applied to the gate electrode of the sixth transistor T6. The first electrode of the sixth transistor T6 may be connected to the third node N3. The second electrode of the sixth transistor T6 may be connected to the second electrode of the seventh transistor T7.

The fifth transistor T5 and the sixth transistor T6 may be turned on or off in response to the emission control signal EM. For example, in case that the emission control signal EM has an activation level, the fifth transistor T5 and the sixth transistor T6 may be turned on. In this case, the fifth transistor T5 and the sixth transistor T6 may provide the driving current Ioled generated from the first transistor T1 to the anode electrode of the light-emitting element LED. Conversely, in case that the emission control signal EM has a deactivated level, the fifth transistor T5 and the sixth transistor T6 may block the supply of the driving current Ioled generated from the first transistor T1.

The seventh transistor T7 may include a gate electrode, a first electrode, and a second electrode. The third gate signal GB may be applied to the gate electrode of the seventh transistor T7. The initialization voltage VINT may be applied to the first electrode of the seventh transistor T7. The second electrode of the seventh transistor T7 may be connected to the second electrode of the sixth transistor T6.

The seventh transistor T7 may be turned on or off in response to the third gate signal GB. For example, in case that the third gate signal GB has an activated level, the seventh transistor T7 may be turned on. In this case, the seventh transistor T7 may provide the initialization voltage VINT to the anode electrode of the light-emitting element LED. Conversely, in case that the third gate signal GB has a deactivated level, the seventh transistor T7 may block the supply of the initialization voltage VINT.

In an embodiment, the first electrode of each of the first, second, third, fourth, fifth, sixth, and seventh transistors T1, T2, T3, T4, T5, T6, and T7 may be a source electrode, and the second electrode of each of the first, second, third, fourth, fifth, sixth, and seventh transistors T1, T2, T3, T4, T5, T6, and T7 may be a drain electrode. However, the embodiments of the present disclosure are not necessarily limited thereto, and the first electrode of at least one of the first, second, third, fourth, fifth, sixth, and seventh transistors T1, T2, T3, T4, T5, T6, and T7 may be a drain electrode, and the second electrode of the remaining of the first, second, third, fourth, fifth, sixth, and seventh transistors T1, T2, T3, T4, T5, T6, and T7 may be a source electrode.

The storage capacitor Cst may include a first electrode and a second electrode. The driving voltage ELVDD may be applied to the first electrode of the storage capacitor Cst. The second electrode of the storage capacitor Cst may be connected to the first node N1.

The light-emitting element LED may include an anode electrode and a cathode electrode. The anode electrode of the light-emitting element LED may be connected to the second electrode of the sixth transistor T6 and the second electrode of the seventh transistor T7. The common voltage ELVSS may be applied to the cathode electrode of the light-emitting element LED. The common voltage ELVSS may have a voltage level lower than the driving voltage ELVDD.

Although FIG. 4 illustrates which one pixel driving circuit PC includes seven transistors and one capacitor, embodiments of the present disclosure are not necessarily limited thereto.

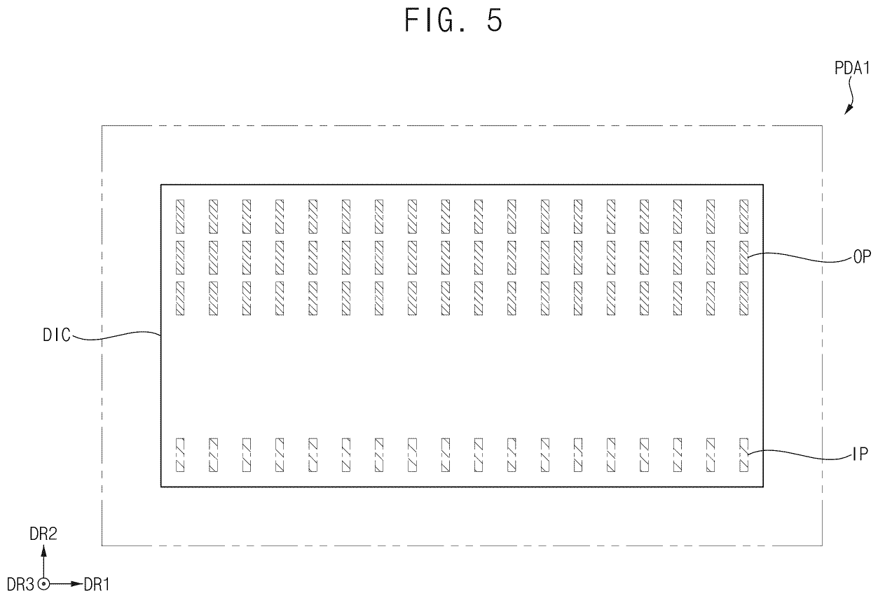

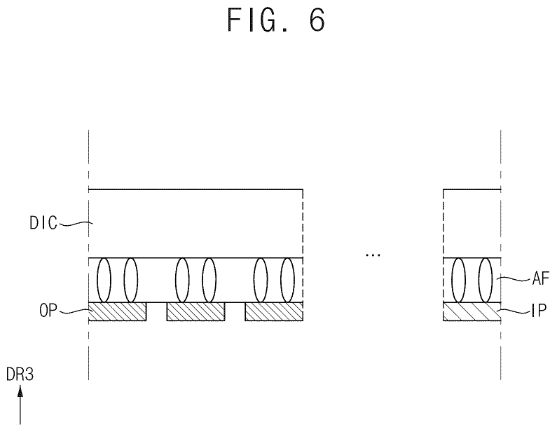

FIG. 5 is a plan view illustrating an enlarged view of a first pad area PDA1 of FIG. 1. FIG. 6 is a cross-sectional view illustrating an example of a driving integrated circuit DIC bonded to a plurality of pads of FIG. 5.

Referring to FIGS. 5 and 6, the display panel DP of FIGS. 1 and 3 may further include a plurality of pads disposed in the first pad area PDA1. The plurality of pads may be repeatedly arranged along the first direction DR1 and along the second direction DR2. For example, the plurality of pads may include an input pad IP provided in plural including a plurality of input pads IP and an output pad OP provided in plural including a plurality of output pads OP. An electrical signal may be input to the driving integrated circuit IC at the input pad IP and an electrical signal may be output from the driving integrated circuit IC at the output pad OP.

The first pad area PDA1 may include a first (planar) area and a second (planar) area. The plurality of input pads IP may be disposed in the first area, and the plurality of output pads OP may be arranged in the second area. For example, each of the first area and the second area may have a length which extends in the first direction DR1. In addition, the second area may be positioned apart from the first area along the second direction DR2.

For example, the plurality of input pads IP may be disposed spaced apart from each other in a single line along the first direction DR1, in the first area. The plurality of output pads OP may be disposed spaced apart from each other in three lines each lengthwise extended along the first direction DR1, in the second area. However, the invention is not limited thereto, and the plurality of input pads IP may be disposed spaced apart from each other in two or more lines along the first direction DR1, and the plurality of output pads OP may be disposed spaced apart from each other in one, two, or four or more lines along the first direction DR1.

The driving integrated circuit DIC may be bonded to the display panel DP at the plurality of input pads IP and the plurality of output pads OP. The driving integrated circuit DIC may be electrically connected to the plurality of input pads IP and the plurality of output pads OP, such as through a conductive film AF.

For example, the conductive film AF may include an anisotropic conductive film. The driving integrated circuit DIC may output an output signal generated based on an input signal transmitted by the plurality of input pads IP, through the plurality of output pads OP.

FIG. 7 is a cross-sectional view taken along line I-I′ of FIG. 1.

Referring to FIGS. 1, 3 and 7, as described above, the display device DD may include the display panel DP, the touch sensor layer 200, the anti-reflection layer 300, and the window member 400, and the display panel DP of FIGS. 1 and 3 may include the substrate 110, the pixel circuit layer 120, the light-emitting element layer 130, and the encapsulation layer 140.

The pixel circuit layer 120 may include first, second, third, and fourth insulating layers IL1, IL2, IL3, and IL4, a transistor TR, an upper electrode CE2, a connection electrode CE, and first and second via insulating layers VIA1 and VIA2, and the light-emitting element layer 130 may include a pixel defining layer PDL and the light-emitting element LED. Here, the transistor TR may include an active pattern ACT, a lower electrode CE1, a source electrode SE, and a drain electrode DE, and the light-emitting element LED may include a pixel electrode PE, a light-emitting layer EML, and a common electrode CME.

The first insulating layer IL1 may be disposed on the substrate 110. The first insulating layer IL1 may prevent metal atoms or impurities from diffusing from the substrate 110 to the transistor TR. In addition, the first insulating layer IL1 may improve the flatness of the surface of the substrate 110 in case that the surface of the substrate 110 is not uniform. For example, the first insulating layer IL1 may include an inorganic material such as silicon oxide (SiOₓ), silicon nitride (SiNₓ), silicon oxynitride (SiOₓN_{y}), and the like. These may be used alone or in combination with each other. The first insulating layer IL1 may have a single-layer structure or a multi-layer structure including a plurality of layers.

The active pattern ACT may be disposed in the display area DA, on the first insulating layer IL1. For example, the active pattern ACT may include an inorganic semiconductor such as amorphous silicon, polycrystalline silicon, or the like. Alternatively, the active pattern ACT may include a metal oxide semiconductor. Examples of the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and the like. These may be used alone or in combination with each other.

The active pattern ACT may have a source region, a drain region, and a channel region positioned between the source region and the drain region. The source region and the drain region may be doped with an impurity (e.g., a P-type impurity or an N-type impurity). The channel region may not be doped with an impurity.

The second insulating layer IL2 may be disposed on the first insulating layer IL1. The second insulating layer IL2 may cover the active pattern ACT and may be disposed along the (cross-sectional) profile of the gate electrode GE with a uniform thickness. Alternatively, the second insulating layer IL2 may sufficiently cover the gate electrode GE and may have a substantially flat upper surface without forming a step around the gate electrode GE. For example, the second insulating layer IL2 may include an inorganic material such as silicon oxide, silicon nitride, silicon oxynitride, and the like. These may be used alone or in combination with each other. The second insulating layer IL2 may have a single-layer structure or a multi-layer structure including a plurality of layers.

The lower electrode CE1 may be disposed in the display area DA, on the second insulating layer IL2. The lower electrode CE1 may overlap the channel area of the active pattern ACT in the plan view. The lower electrode CE1 may be a gate electrode of the transistor TR.

The lower electrode CE1 may include a metal, an alloy, a metal nitride, a conductive metal oxide, a transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNₓ), and the like. These may be used alone or in combination with each other. The lower electrode CE1 may have a single-layer structure or a multi-layer structure including a plurality of layers.

The third insulating layer IL3 may be disposed on the second insulating layer IL2. The third insulating layer IL3 may cover the lower electrode CE1 and may be disposed along the profile of the lower electrode CE1 with a uniform thickness. Alternatively, the third insulating layer IL3 may sufficiently cover the lower electrode CE1 and may have a substantially flat upper surface without forming a step around the lower electrode CE1. For example, the third insulating layer IL3 may include an inorganic material such as silicon oxide, silicon nitride, silicon oxynitride, and the like. These may be used alone or in combination with each other. The third insulating layer IL3 may have a single-layer structure or a multi-layer structure including a plurality of layers.

The upper electrode CE2 may be disposed in the display area DA, on the third insulating layer IL3. The upper electrode CE2 may overlap the lower electrode CE1 in the plan view. For example, the upper electrode CE2 may include a metal, an alloy, a metal nitride, a conductive metal oxide, a transparent conductive material, and the like. These may be used alone or in combination with each other. The upper electrode CE2 may have a single-layer structure or a multi-layer structure including a plurality of layers.

The fourth insulating layer IL4 may be disposed on the third insulating layer IL3. The fourth insulating layer IL4 may cover the upper electrode CE2 and may be disposed along the profile of the upper electrode CE2 with a uniform thickness. Alternatively, the fourth insulating layer IL4 may sufficiently cover the upper electrode CE2 and may have a substantially flat upper surface without forming a step around the upper electrode CE2. For example, the fourth insulating layer IL4 may include an inorganic material such as silicon oxide, silicon nitride, silicon oxynitride, and the like. These may be used alone or in combination with each other. The fourth insulating layer IL4 may have a single-layer structure or a multi-layer structure including a plurality of layers.

The first, second, third, and fourth insulating layers IL1, IL2, IL3, and IL4 may be collectively defined as an inorganic insulating layer IL. That is, the inorganic insulating layer IL may include one or more of the first, second, third, and fourth insulating layers IL1, IL2, IL3, and IL4.

The source electrode SE and the drain electrode DE may be disposed in the display area DA on the fourth insulating layer IL4. The source electrode SE may be connected to the source region of the active pattern ACT through a first contact hole penetrating the second, third, and fourth insulating layers IL2, IL3, and IL4. The drain electrode DE may be connected to the drain region of the active pattern ACT through a second contact hole penetrating the second, third, and fourth insulating layers IL2, IL3, and IL4. The source electrode SE and the drain electrode DE may be disposed in the same layer and may include the same material. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

For example, the source electrode SE and the drain electrode DE may include a metal, an alloy, a metal nitride, a conductive metal oxide, a transparent conductive material, and the like. These may be used alone or in combination with each other. The source electrode SE and the drain electrode DE may each have a single-layer structure or a multi-layer structure including a plurality of layers.

Accordingly, the transistor TR including the active pattern ACT, the lower electrode CE1, the source electrode SE, and the drain electrode DE may be formed in the display area DA. For example, the transistor TR may correspond to the sixth transistor T6 of FIG. 4. Alternatively, the transistor TR may be a driving transistor.

The first via insulating layer VIA1 may be disposed on the fourth insulating layer IL4. The first via insulating layer VIA1 may sufficiently cover the source electrode SE and the drain electrode DE. To this end, the first via insulating layer VIA1 may have a substantially flat upper surface. The first via insulating layer VIA1 may include an organic material. For example, the first via insulating layer VIA1 may include an organic material such as an acrylic resin, BCB (benzocyclobutene), HMDSO (hexamethyldisiloxane), and the like. These may be used alone or in combination with each other. The first via insulating layer VIA1 may have a single-layer structure or a multi-layer structure including a plurality of layers.

The connection electrode CE may be disposed in the display area DA on the first via insulating layer VIA1. The connection electrode CE may be connected to the drain electrode DE (or, the source electrode SE) through a contact hole penetrating (e.g., completely through a thickness of) the first via insulating layer VIA1. For example, the connection electrode CE may include a metal, an alloy, a metal nitride, a conductive metal oxide, a transparent conductive material, and the like. These may be used alone or in combination with each other. The connection electrode CE may have a single-layer structure or a multi-layer structure including a plurality of layers.

The second via insulating layer VIA2 may be disposed on the first via insulating layer VIA1. The second via insulating layer VIA2 may sufficiently cover the connection electrode CE. To this end, the second via insulating layer VIA2 may have a substantially flat upper surface. The second via insulating layer VIA2 may include an organic material. For example, the second via insulating layer VIA2 may include an organic material such as an acrylic resin, BCB (benzocyclobutene), HMDSO (hexamethyldisiloxane), and the like. These may be used alone or in combination with each other. The second via insulating layer VIA2 may have a single-layer structure or a multi-layer structure including a plurality of layers.

The first and second via insulating layers VIA1 and VIA2 may be collectively defined as an organic insulating layer VIA. That is, the organic insulating layer VIA may include the first and second via insulating layers VIA1 and VIA2.

The pixel electrode PE may be disposed in the display area DA, on the second via insulating layer VIA2. The pixel electrode PE may be connected (e.g., electrically) to the connection electrode CE through a contact hole penetrating the second via insulating layer VIA2. For example, the pixel electrode PE may include a metal, an alloy, a metal nitride, a conductive metal oxide, a transparent conductive material, and the like. These may be used alone or in combination with each other. The pixel electrode PE may have a single-layer structure or a multi-layer structure including a plurality of layers. In addition, the pixel electrode PE may operate as an anode.

The light-emitting layer EML may be disposed on the pixel electrode PE. Specifically, the light-emitting layer EML may be disposed in a pixel opening which is defined in (or by) a material of the pixel defining layer PDL. The light-emitting layer EML may include a light-emitting material which emits preset light (e.g., red light, green light, or blue light). For example, the light-emitting material may include an organic light-emitting material or an inorganic light-emitting material (e.g., quantum dots). However, the embodiments of the present disclosure are not necessarily limited thereto.

The common electrode CME may be disposed on the light-emitting layer EML and on the pixel defining layer PDL. The common electrode CME may be disposed on the whole surface of the display area DA. The common electrode CME may include a semi-transparent or transparent electrode. For example, the common electrode CME may include a conductive material having a low work function. The common electrode CME may have a single-layer structure or a multi-layer structure including a plurality of layers.

The encapsulation layer 140 may be disposed on the common electrode CME. The touch sensor layer 200 may be disposed on the encapsulation layer 140. The touch sensor layer 200 may include a first touch electrode TE1, a touch insulating layer TIL, a second touch electrode TE2, and a touch protection layer PL.

The first touch electrode TE1 may be disposed in the display area DA, on the encapsulation layer 140. The first touch electrode TE1 may include a metal, an alloy, a transparent conductive material, and the like. Examples of the metal may include molybdenum (Mo), silver (Ag), titanium (Ti), copper (Cu), and the like. Examples of the transparent conductive material may include indium tin oxide (ITO), indium zinc oxide (IZO), zinc oxide (ZnO), indium tin zinc oxide (ITZO), conductive polymers, metal nanowires, carbon nanotubes, graphene, and the like. Each of these may be used alone or in combination with each other.

The touch insulating layer TIL may be disposed on the encapsulation layer 140. The touch insulating layer TIL may cover the first touch electrode TE1. For example, the touch insulating layer TIL may include an inorganic material (e.g., a touch inorganic insulating layer). Examples of the inorganic material may include a silicon compound such as silicon oxide, silicon nitride, silicon oxynitride, and the like. These may be used alone or in combination with each other. The touch insulating layer TIL as the touch inorganic insulating layer may include silicon, such as in the form of silicon nitride.

The second touch electrode TE2 may be disposed in the display area DA, on the touch insulating layer TIL. The second touch electrode TE2 may function as a sensor which detects an external input such as a user's touch. For example, both the first touch electrode TE1 and the second touch electrode TE2 may function as sensors. In this case, the second touch electrode TE2 may be electrically connected to the first touch electrode TE1. Specifically, the second touch electrode TE2 may be connected to the first touch electrode TE1 through a contact hole penetrating the touch insulating layer TIL. For example, the second touch electrode TE2 may include a metal, an alloy, a transparent conductive material, and the like. These may be used alone or in combination with each other.

For example, the first touch electrode TE1 and the second touch electrode TE2 may have a mesh structure in the plan view.

The touch protection layer PL may be disposed on the touch insulating layer TIL. The touch protection layer PL may sufficiently cover the second touch electrode TE2. That is, the touch protection layer PL may have a substantially flat upper surface. For example, the touch protection layer PL may include an organic material. Examples of the organic material may include an acrylic resin, a methacrylic resin, a vinyl resin, an epoxy resin, a urethane resin, a cellulose resin, a perylene resin, and the like. These may be used alone or in combination with each other.

The anti-reflection layer 300 may be disposed on the touch sensor layer 200. The description of the anti-reflection layer 300 is the same as that described with reference to FIG. 3.

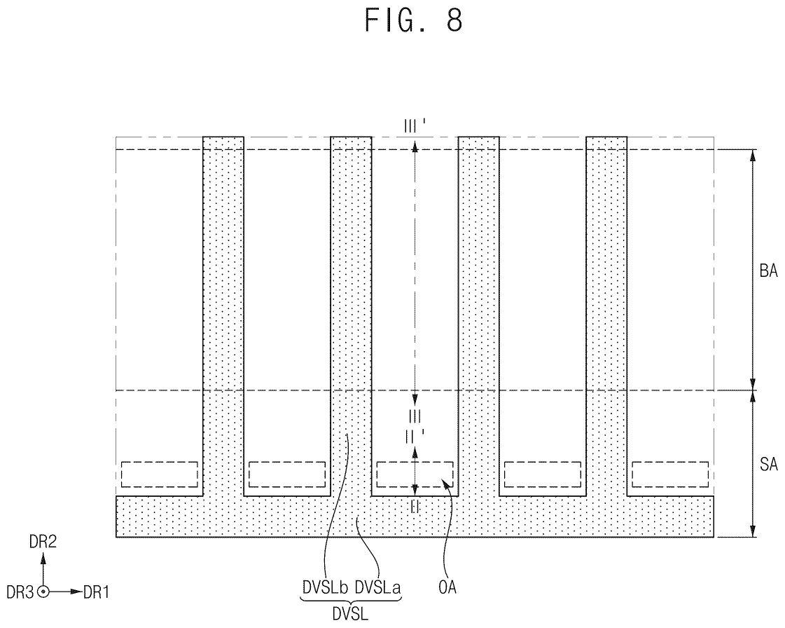

FIG. 8 is an enlarged plan view illustrating a portion of a bending area BA and a sub-area SA of the display device DD of FIG. 1.

Referring to FIG. 8, in an embodiment, the sub-area SA may include an opening area OA provided in plural including a plurality of opening areas OA adjacent to the bending area BA. The opening areas OA refer to (planar) areas where two inorganic layers are in direct contact with each other. Since the two inorganic layers are in direct contact in the opening areas OA, moisture permeation due to exposure of an organic layer may be prevented. As being in contact, elements or layers may form an interface therebetween.

In an embodiment, the driving voltage supply line DVSL may include a body portion DVSLa at which the driving voltage supply line DVSL is (electrically) connected to the circuit board CB of FIG. 1, and branch portions DVSLb branched from the body portion DVSLa. The branch portions DVSLb may extend in the second direction DR2, respectively. In addition, the branch portions DVSLb may be spaced apart from each other along the first direction DR1 by gaps.

For example, the plurality of opening areas OA may be positioned within the gaps between the branch portions DVSLb in the plan view, respectively.

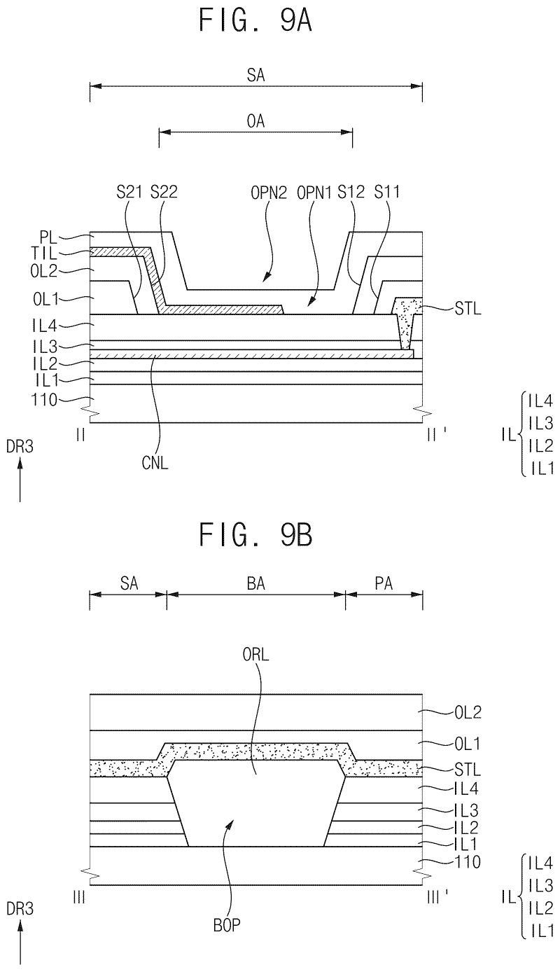

FIGS. 9A and 9B are cross-sectional views taken along lines II-II′ and III-III′ of FIG. 8, respectively. Hereinafter, descriptions which overlap with the content explained with reference to FIG. 7 will be omitted or simplified.

Referring to FIGS. 7, 9A and 9B, the display panel DP of FIGS. 1 and 3 may further include a connection line CNL, a signal transmission line STL, an organic material layer ORL, and first and second organic layers OL1 and OL2.

The inorganic insulating layer IL may be disposed on the substrate 110. The inorganic insulating layer IL may extend from the display area DA to at least a portion of the sub-area SA. In addition, the inorganic insulating layer IL may extend from the display area DA to at least a portion of the peripheral area PA excluding the sub-area SA. In an embodiment, the inorganic insulating layer IL extends continuously from the display area DA to the peripheral area PA and/or to the sub-area SA.

The inorganic insulating layer IL may not be disposed in the bending area BA, that is, is excluded from the bending area BA. That is, a bending opening BOP overlapping the bending area BA may be defined in the inorganic insulating layer IL. The bending opening BOP may expose at least a portion of the substrate 110 in the bending area BA, to outside the inorganic insulating layer IL.

The connection line CNL may be disposed between the second insulating layer IL2 and the third insulating layer IL3. The connection line CNL may be disposed in the same layer as the lower electrode CE1 of FIG. 7. That is, the connection line CNL may include the same material as the lower electrode CE1 of FIG. 7 and may be formed through the same process as the lower electrode CE1 of FIG. 7. Various signals, voltages, and the like may be applied to the connection line CNL. For example, the data voltage may be applied to the connection line CNL.

The organic material layer ORL as a discrete pattern may be disposed in the bending area BA on the substrate 110. Specifically, the organic material layer ORL may fill a volume of the bending opening BOP. For example, the organic material layer ORL may include the same material as the first via insulating layer VIA1 of FIG. 7 and may be formed through the same process as the first via insulating layer VIA1 of FIG. 7. However, the embodiments of the present disclosure are not necessarily limited thereto. The organic material layer ORL may compensate for the step formed by the inorganic layer sidewalls which define bending opening BOP at the bending area BA and absorb stress generated by the bending of the display panel DP at the bending area BA.

The signal transmission line STL may be disposed on the fourth insulating layer IL4 and the organic material layer ORL. The signal transmission line STL may include the same material as the connection electrode CE of FIG. 7 and may be formed through the same process as the connection electrode CE of FIG. 7. The signal transmission line STL may be connected to the connection line CNL through a contact hole penetrating the third insulating layer IL3 and the fourth insulating layer IL4, in the sub-area SA. Accordingly, the signal transmission line STL may receive various signals, voltages, and the like from the connection line CNL. For example, the signal transmission line STL may receive the data voltage from the connection line CNL. In this case, the signal transmission line STL may be the data line DL of FIG. 1.

The first organic layer OL1 may be disposed on the fourth insulating layer IL4 and the signal transmission line STL. The first organic layer OL1 may overlap the sub-area SA, the bending area BA, and the peripheral area PA. The first organic layer OL1 may cover the signal transmission line STL. The first organic layer OL1 may include the same material as the second via insulating layer VIA2 of FIG. 7 and may be formed through the same process as the second via insulating layer VIA2 of FIG. 7.

In an embodiment, a first opening OPN1 overlapping the opening area OA may be defined in the first organic layer OL1. The first opening OPN1 may expose at least a portion of the fourth insulating layer IL4 in the opening area OA to outside the first organic layer OL1. The first opening OPN1 may be defined by a first-first side surface S11 of the first organic layer OL1 and a second-first side surface S21 which is opposite to the first-first side surface S11. The first-first side surface S11 may be positioned adjacent to the bending area BA (e.g., closer to the bending area BA), and the second-first side surface S21 may face the first-first side surface S11 across the first opening OPN1.

The second organic layer OL2 may be disposed on the first organic layer OL1. The second organic layer OL2 may overlap the sub-area SA, the bending area BA, and the peripheral area PA. The second organic layer OL2 may include the same material as the pixel defining layer PDL of FIG. 7 and may be formed through the same process as the pixel defining layer PDL of FIG. 7.

In an embodiment, a second opening OPN2 overlapping the opening area OA may be defined in the second organic layer OL2. That is, the second opening OPN2 may overlap the first opening OPN1 in the plan view. At this time, a width of the second opening OPN2 may be smaller than a width of the first opening OPN1, owing to a portion of the second organic layer OL2 extended into the first opening OPN1. That is, the second organic layer OL2 may cover the first-first side surface S11 and the second-first side surface S21 of the first organic layer OL1 which define the first opening OPN1.

The second opening OPN2 may have a first-second side surface S12 of the second organic layer OL2 and a second-second side surface S22 which is opposite to the first-second side surface S12. The first-second side surface S12 may be positioned adjacent to the bending area BA (e.g., closer to the bending area BA than the second-second side surface S22), and the second-second side surface S22 may face the first-second side surface S12. That is, the first-second side surface S12 may be adjacent to the first-first side surface S11, and the second-second side surface S22 may be adjacent to the second-first side surface S21, to define pairs of corresponding side surfaces.

The first-first side surface S11 and the first-second side surface S12 may be collectively referred to as a first side surface at a first side of the opening area OA, and the second-first side surface S21 and the second-second side surface S22 may be collectively referred to as a second side surface at a second side of the opening area OA which is opposite to the first side.

The touch insulating layer TIL may extend from the display area DA to at least a portion of the sub-area SA. In an embodiment, the touch insulating layer TIL may be spaced apart from the first-first side surface S11 and the first-second side surface S12, and may cover the second-first side surface S21 and the second-second side surface S22. That is, the touch insulating layer TIL may not overlap the first-first side surface S11 and the first-second side surface S12 in the plan view. Specifically, in the sub-area SA, the touch insulating layer TIL may directly contact the second-second side surface S22 and an upper surface of the fourth insulating layer IL4 which is exposed to outside the second organic layer OL2. The touch insulating layer TIL may not overlap the bending area BA.

For example, the touch insulating layer TIL may have a relatively small density (e.g., about 1.9 grams per cubic centimeter (g/cm³)). Alternatively, the touch insulating layer TIL may have a relatively large density (e.g., about 2.15 g/cm³).

The touch protection layer PL may extend from the display area DA to at least a portion of the sub-area SA. The touch protection layer PL may cover the touch insulating layer TIL and the second organic layer OL2 in the sub-area SA. In an embodiment, in the sub-area SA, the touch protection layer PL may directly contact the first-second side surface S12 and the upper surface of the fourth insulating layer IL4. The touch protection layer PL may not overlap the bending area BA.

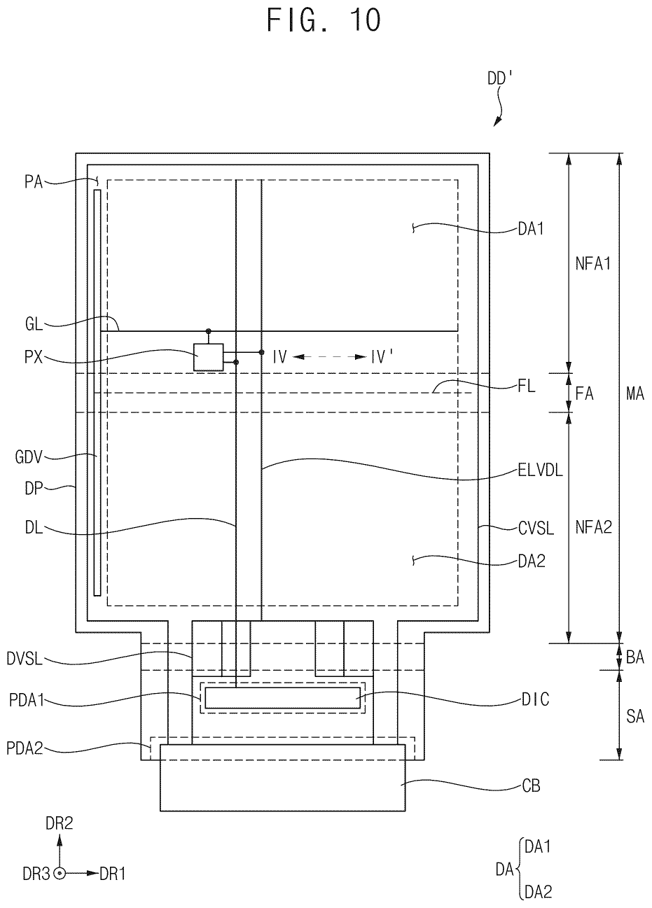

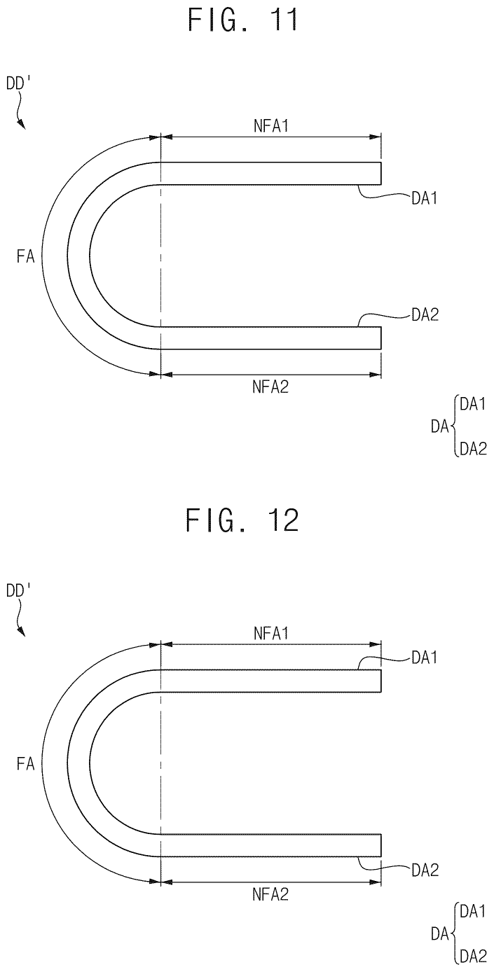

FIG. 10 is a plan view illustrating a display device DD′ according to an embodiment of the present disclosure. FIGS. 11 and 12 are cross-sectional views illustrating a folding state of the display device DD′ of FIG. 10, that is, the display device DD′ which is folded.

Referring to FIG. 10, a display device DD′ according to an embodiment of the present disclosure may include the display panel DP, the gate driver GDV, the driving integrated circuit DIC, and the circuit board CB. However, the display device DD′ described with reference to FIG. 10 may be substantially the same as or similar to the display device DD described with reference to FIG. 1, except that the display device DD′ includes a foldable area FA. Hereinafter, redundant description will be omitted or simplified.

The display device DD′ may have at least a portion which is flexible and may be folded at the portion which is flexible (e.g., the foldable area FA). That is, the main area MA may include the foldable area FA which can be bent by an external force so that the display device DD′ can be folded, and a non-folding area provided in plural such as first and second non-folding areas NFA1 and NFA2 which are adjacent to at least one side of the foldable area FA and are not folded. For example, the foldable area FA may include a folding line FL extending along the first direction DR1 and about which the display panel DP is foldable. Here, the non-folding area is for convenience of explanation, and the expression “non-folding” includes not only cases where such portion of the display device DD′ it is rigid and has no flexibility, but also cases where such portion is flexible but has less flexibility than the foldable area FA and does not fold.

The display area DA may be divided into a first display area DA1 and a second display area DA2. Specifically, the first display area DA1 and the second display area DA2 may be adjacent to each other in the second direction DR2. The first display area DA1 and the second display area DA2 may be continuously connected to form substantially one display area DA. For example, in case that the display device DD′ is folded along the folding line FL, the display device DD′ may have an in-folding structure so that a display surface at the first display area DA1 and the second display area DA2 face each other, as illustrated in FIG. 11. Alternatively, in case that the display device DD′ is folded along the folding line FL, the display device DD′ may have an out-folding structure in which the display surface at the first display area DA1 and the second display area DA2 are disposed on the outside, as illustrated in FIG. 12, such as to face away from each other. In an embodiment, the overall display area DA may further include the folding area FA as an area at which an image is displayed, in addition to the first display area DA1 and the second display area DA2.

In addition, although the display device DD′ is illustrated in FIG. 10 as having one foldable area FA, the display device DD′ according to embodiments of the present disclosure is not limited to having one foldable area FA. For example, the display device DD′ may have multiple foldable areas so as to be folded at multiple locations or to implement a rollable display device.

FIG. 13 is a cross-sectional view taken along line IV-IV′ of FIG. 10.

Referring to FIGS. 3, 10 and 13, the display device DD′ may include the display panel DP, the touch sensor layer 200, the anti-reflection layer 300, and the window member 400, and the display panel DP of FIG. 10 may include the substrate 110, the pixel circuit layer 120, the light-emitting element layer 130, and the encapsulation layer 140.

The pixel circuit layer 120 may include the first, second, third, and fourth insulating layers IL1, IL2, IL3, and IL4, the transistor TR, the upper electrode CE2, the connection electrode CE, and the first and second via insulating layers VIA1 and VIA2, and the light-emitting element layer 130 may include the pixel defining layer PDL and the light-emitting element LED. Here, the transistor TR may include the active pattern ACT, the lower electrode CE1, the source electrode SE, and the drain electrode DE, and the light-emitting element LED may include the pixel electrode PE, the light-emitting layer EML, and the common electrode CME.

The display device DD′ described with reference to FIG. 13 may be substantially the same as or similar to the display device DD described with reference to FIG. 7, except for the structures of the touch sensor layer 200 and the anti-reflection layer 300. Hereinafter, redundant description will be omitted or simplified.

The touch sensor layer 200 may be disposed on the encapsulation layer 140. The touch sensor layer 200 may include the first touch electrode TE1, the touch insulating layer TIL, the second touch electrode TE2, and a touch protection layer PL′.

The first touch electrode TE1 may be disposed in the display area DA, on the encapsulation layer 140. The touch insulating layer TIL may be disposed on the encapsulation layer 140. The touch insulating layer TIL may cover the first touch electrode TE1. For example, the touch insulating layer TIL may include an inorganic material.

The second touch electrode TE2 may be disposed in the display area DA, on the touch insulating layer TIL. The second touch electrode TE2 may be connected to the first touch electrode TE1 through a contact hole penetrating the touch insulating layer TIL.

The touch protection layer PL′ may be disposed on the touch insulating layer TIL. The touch protection layer PL′ may cover the second touch electrode TE2. For example, the touch protection layer PL′ may cover the second touch electrode TE2 and may be disposed along the profile of the second touch electrode TE2 with a uniform thickness. The touch protection layer PL′ may have an upper surface corresponding to the cross-sectional profile of the electrode layer including the second touch electrode TE2, instead of having a planarized upper surface like the touch protection layer PL.

For example, the touch protection layer PL′ may include an inorganic material. Examples of the inorganic material may include a silicon compound such as silicon oxide, silicon nitride, silicon oxynitride, and the like. These may be used alone or in combination with each other. In an embodiment, the touch protection layer PL′ may include silicon nitride.

In an embodiment, the anti-reflection layer 300 may include a black matrix BM, a color filter CF, and an overcoat layer OC.

The black matrix BM may be disposed in the display area DA, on the touch protection layer PL′. Specifically, the black matrix BM may overlap a material portion of the pixel defining layer PDL in the plan view. For example, the black matrix BM may include a light-blocking material. An opening exposing at least a portion of the touch protection layer PL′ may be defined in the black matrix BM.

The color filter CF may be disposed on the touch protection layer PL′ and the black matrix BM. Specifically, the color filter CF may be disposed in the opening of the black matrix BM. The color filter CF may be a red color filter which transmits red light, a green color filter which transmits green light, or a blue color filter which transmits blue light.

The overcoat layer OC may be disposed on the color filter CF and the black matrix BM. The overcoat layer OC may have a substantially flat upper surface. For example, the overcoat layer OC may include an organic material such as an acrylic resin (e.g., an organic overcoat layer).

Accordingly, reflection of external light may be prevented through the anti-reflection layer 300 including the black matrix BM, the color filter CF, and the overcoat layer OC.

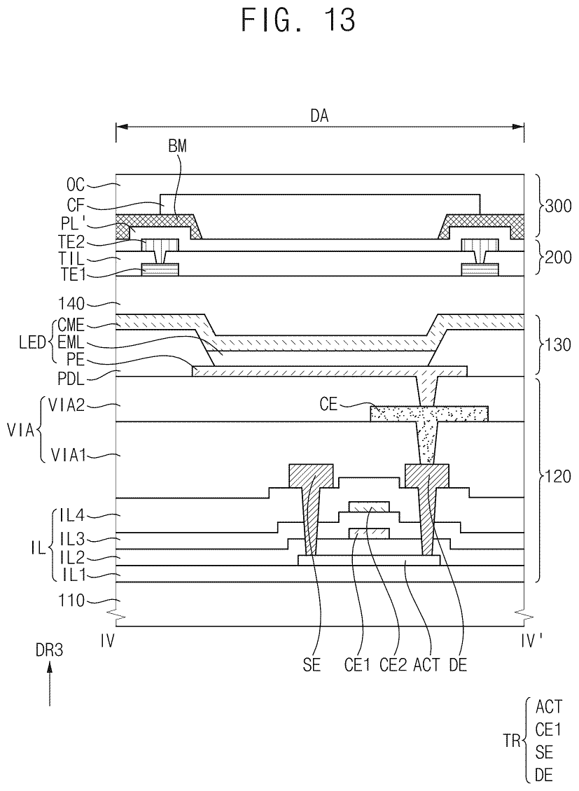

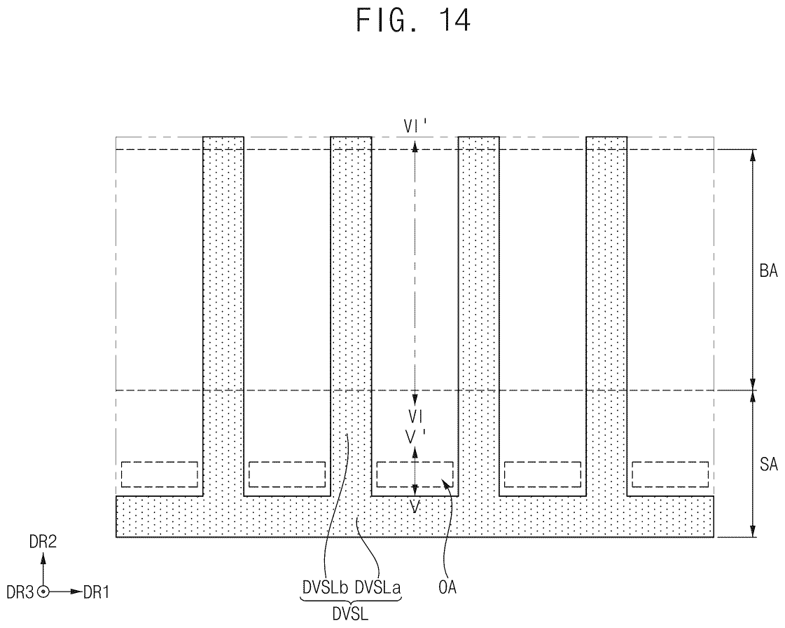

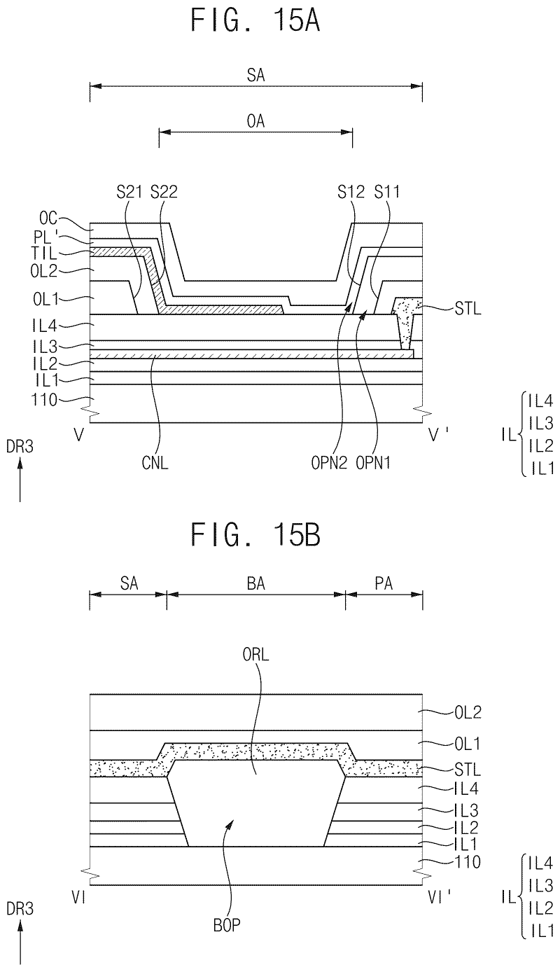

FIG. 14 is a plan view illustrating an enlarged view of a portion of a bending area BA and a sub-area SA of the display device DD′ of FIG. 10. FIGS. 15A and 15B are cross-sectional views illustrating an example of a cross-section taken along lines V-V′ and the VI-VI′ of FIG. 14, respectively.

The display device DD′ described with reference to FIGS. 14, 15A and 15B may be substantially the same as or similar to the display device DD described with reference to FIGS. 8 and 9, except for the touch protection layer PL′ and the overcoat layer OC. Hereinafter, redundant description will be omitted.

Referring to FIGS. 14, 15A and 15B, the touch insulating layer TIL may extend from the display area DA to at least a portion of the sub-area SA. In an embodiment, the touch insulating layer TIL may be spaced apart from the first-first side surface S11 and the first-second side surface S21, and may cover the second-first side surface S21 and the second-second side surface S22. Specifically, in the sub-area SA, the touch insulating layer TIL may directly contact the second-second side surface S22 and the upper surface of the fourth insulating layer IL4. The touch insulating layer TIL may not overlap the bending area BA.

The touch protection layer PL′ may extend from the display area DA to at least a portion of the sub-area SA. The touch protection layer PL′ may not overlap the bending area BA.

In an embodiment, the touch protection layer PL′ may cover the touch insulating layer TIL and the second organic layer OL2. In this case, the touch protection layer PL′ may directly contact the first-second side surface S12 and the upper surface of the fourth insulating layer IL4. Since the touch protection layer PL′ including the inorganic material has a lower oxidation rate due to moisture than the touch insulating layer TIL, outgassing bubbles due to oxidation may not occur.

In an embodiment, the overcoat layer OC may extend from the display area DA to at least a portion of the sub-area SA. The overcoat layer OC may be disposed on the touch protection layer PL′ in the sub-area SA. For example, the overcoat layer OC may be disposed directly on the touch protection layer PL′ in the sub-area SA. The overcoat layer OC may not overlap the bending area BA.

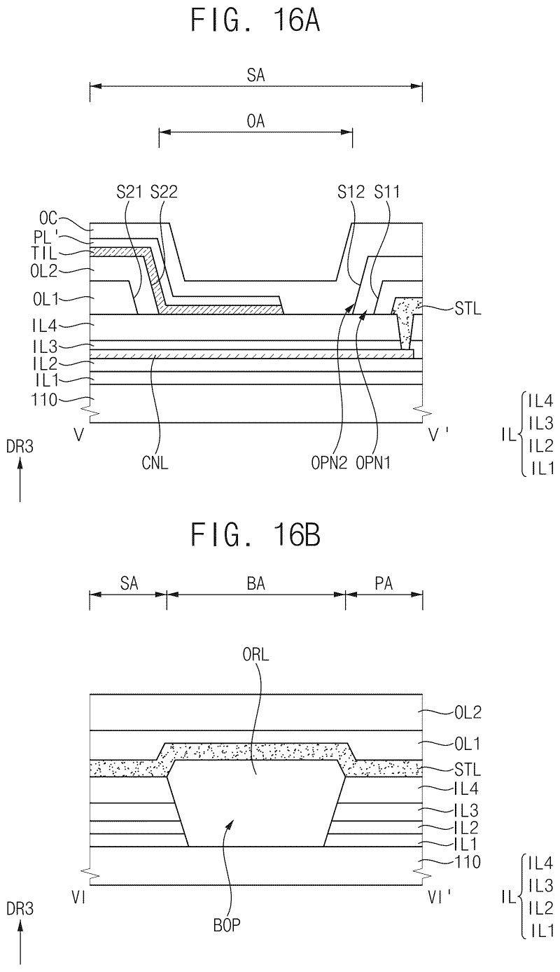

FIGS. 16A and 16B are cross-sectional views illustrating an example of a cross-section taken along lines V-V′ and the VI-VI′ of FIG. 14, respectively.

The display device DD′ described with reference to FIGS. 14, 16A and 16B may be substantially the same as or similar to the display device DD described with reference to FIGS. 8, 9A and 9B, except for the touch protection layer PL′ and the overcoat layer OC. Hereinafter, redundant description will be omitted.

Referring to FIGS. 14, 16A and 16B, the touch insulating layer TIL may extend from the display area DA to at least a portion of the sub-area SA. In an embodiment, the touch insulating layer TIL may be spaced apart from the first-first side surface S11 and the first-second side surface S12, and may cover the second-first side surface S21 and the second-second side surface S22. Specifically, in the sub-area SA, the touch insulating layer TIL may directly contact the second-second side surface S22 and the upper surface of the fourth insulating layer IL4. The touch insulating layer TIL may not overlap the bending area BA.

The above touch protection layer PL′ may extend from the display area DA to at least a portion of the sub-area SA. The touch protection layer PL′ may not overlap the bending area BA.

In an embodiment, the touch protection layer PL′ may be spaced apart from the first-first side surface S11 and the first-second side surface S12, and may cover the second-first side surface S21 and the second-second side surface S22. That is, the touch protection layer PL′ may not overlap the first-first side surface S11 and the first-second side surface S12 in the plan view.

For example, as illustrated in FIGS. 16 and 16B, the end of the touch protection layer PL′ may coincide with the end of the touch insulating layer TIL. In an embodiment, the end surfaces of the two layers may be coplanar with each other. Alternatively, unlike as illustrated in FIGS. 16A and 16B, the touch protection layer PL′ may extend further than the end of the touch insulating layer TIL to cover the end of the touch insulating layer TIL, or the end of the touch insulating layer TIL may protrude further toward the bending area BA than the end of the touch protection layer PL′ to have an extended portion of the touch insulating layer TIL which is non-overlapping with the touch protection layer PL′.

The overcoat layer OC may extend from the display area DA to at least a portion of the sub-area SA. The overcoat layer OC may cover the touch protection layer PL′ and the second organic layer OL2 in the sub-area SA. In an embodiment, in the sub-area SA, the overcoat layer OC may directly contact the upper surface of the touch protection layer PL′, the second-first side surface S21 and the upper surface of the fourth insulating layer IL4. The overcoat layer OC may not overlap the bending area BA.

Moisture may penetrate into the first and second organic layers OL1 and OL2 at positions thereof which area adjacent (or closest) to the bending area BA. Meanwhile, unlike FIGS. 9A and 9B, 15 and 15B, and 16A and 16B, in case that the touch insulating layer TIL entirely contacts the upper surface of the fourth insulating layer IL4 in the opening area OA and covers the first-first side surface S11, the first-second side surface S12, and the upper surface of the second organic layer OL2 adjacent to the bending area BA, moisture which has penetrated into the first and second organic layers OL1 and OL2 adjacent to the bending area BA may cause the touch insulating layer TIL to be oxidized, thereby generating outgassing bubbles. In particular, in case that the touch insulating layer TIL has a relatively low density, the touch insulating layer TIL may be vulnerable to oxidation due to moisture. Cracks may occur in the touch insulating layer TIL due to the outgassing bubbles, and if moisture penetrates into the cracks, corrosion may occur in signal line such as the data line DL.

Referring again to FIGS. 1 to 16B, in the display devices DD and DD′ according to embodiments of the present disclosure, the organic layer (e.g., the first and second organic layers OL1 and OL2) disposed in the sub-area SA, on the inorganic insulating layer IL, may define the opening (e.g., the first and second openings OPN1 and OPN2) having the first side surface (e.g., the first-first and first-second side surfaces S11 and S12) which is closest to the bending area BA, and the second side surface (e.g., the second-first and second-second side surfaces S21 and S22) which is opposite to the first side surface, and the touch insulating layer TIL may cover the second side surface without overlapping the first side surface in the plan view in the sub-area SA. That is, the touch insulating layer TIL may be disconnected from other material patterns of the touch insulating material layer, at the bending area BA.

Accordingly, oxidation of the touch insulating layer TIL due to the moisture penetrating into the first and second organic layers OL1 and OL2 adjacent to the bending area BA may not occur, and outgassing bubbles may not occur. Accordingly, cracks in the touch insulating layer TIL and corrosion of signal line such as the data line DL may be prevented.

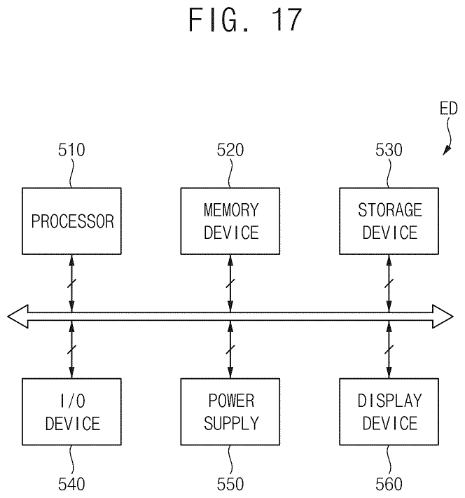

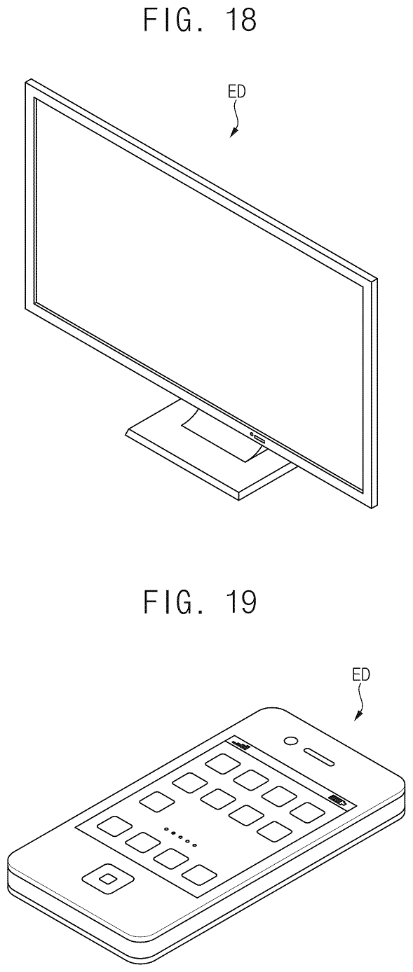

FIG. 17 is a block diagram illustrating an electronic device ED including a display device 560 according to one or more embodiments of the present disclosure. FIG. 18 is a perspective view illustrating an example of the electronic device ED of FIG. 17 being implemented as a television. FIG. 19 is a perspective view illustrating an example of the electronic device ED of FIG. 17 being implemented as a smartphone.

Referring to FIGS. 17, 18, and 19, in an embodiment, an electronic device ED may include a processor 510, a memory device 520, a storage device 530, an input/output device 540, a power supply 550, and a display device 560. In this case, the display device 560 may correspond to the display device DD described with reference to FIGS. 1 to 9B or the display device DD′ described with reference to FIGS. 10 to 16B. The electronic device ED may further include several ports capable of communicating with a video card, a sound card, a memory card, a USB device, and the like.

In an embodiment, as illustrated in FIG. 18, the electronic device ED may be implemented as a television. In an embodiment, as illustrated in FIG. 19, the electronic device ED may be implemented as a smartphone. However, the electronic device ED is not limited thereto, and for example, the electronic device ED may be implemented as a mobile phone, a video phone, a smart pad, a smart watch, a tablet PC, a vehicle navigation device, a computer monitor, a laptop computer, a head mounted display (HMD), and the like.

The processor 510 may perform certain calculations or tasks. In an embodiment, the processor 510 may be a microprocessor, a central processing unit (CPU), an application processor (AP), and/or the like. The processor 510 may be connected to other components through an address bus, a control bus, a data bus, and the like. The processor 510 may also be connected to an expansion bus, such as a peripheral component interconnect (PCI) bus.

The memory device 520 may store data necessary for the operation of the electronic device ED. For example, the memory device 520 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 530 may include a solid state drive (SSD), a hard disk drive (HDD), a CD-ROM, and the like.

The input/output device 540 may include input means such as a keyboard, keypad, touch pad, touch screen, mouse, and the like and output means such as a speaker, a printer, and the like.

The power supply 550 may supply power necessary for the operation of the electronic device ED. The display device 560 may be connected to other components through buses or other communication links. In an embodiment, the display device 560 may be included in the input/output device 540.

The present disclosure can be applied to various display devices which can be equipped with a display device 560. For example, the present disclosure can be applied to high-resolution smartphones, mobile phones, smart pads, smartwatches, tablet PCs, in-vehicle navigation systems, televisions, computer monitors, laptops, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including:
a display area including a pixel, and
a peripheral area adjacent to the display area and including a sub-area and a bending area which is between the display area and the sub-area;
an inorganic insulating layer in the display area and the peripheral area, on the substrate;
an organic layer in the display area and the peripheral area, on the inorganic insulating layer, and in which an opening is defined in the sub-area, the opening exposing the inorganic insulating layer to outside the organic layer and defined by:
a first side surface of the organic layer, and
a second side surface of the organic layer which is opposite to the first side surface and further from the bending area than the first side surface; and
a touch sensor layer on the organic layer and including:
a first touch electrode overlapping the display area;
a touch inorganic insulating layer including:
a first portion covering the first touch electrode, in the display area, and
a second portion covering the second side surface of the organic layer and not overlapping the first side surface of the organic layer, in the sub-area;
a second touch electrode in the display area, on the touch inorganic insulating layer; and
a touch protection layer covering the second touch electrode.

2. The display device of claim 1, wherein
an upper surface of the inorganic insulating layer is exposed to outside the organic layer by the opening, and
the touch inorganic insulating layer directly contacts the upper surface of the inorganic insulating layer and the second side surface of the organic layer, in the sub-area.

3. The display device of claim 1, wherein
the organic layer includes:
a first organic layer in which a first opening of the opening is defined;
the first opening exposing the inorganic insulating layer to outside the first organic layer and defined by a first-first side surface and a second-first side surface which is opposite to the first-first side surface and further from the bending area than the first-first side surface;
a second organic layer which is on the first organic layer and in which a second opening of the opening is defined, the second opening having a width smaller than a width of the first opening and overlapping the first opening; and
the second opening defined by:
a first-second side surface defining the first side surface of the organic layer, and
a second-second side surface which is opposite to the first-second side surface, further from the bending area than the first-second side surface and defines the second side surface of the organic layer, and
the touch inorganic insulating layer directly contacts the second-second side surface of the organic layer.

4. The display device of claim 3, further comprising:
a first via insulating layer in the display area, on the inorganic insulating layer;
a second via insulating layer in the display area, on the first via insulating layer;
a pixel electrode on the second via insulating layer; and
a pixel defining layer in which a pixel opening is defined, the pixel opening exposing the pixel electrode to outside the pixel defining layer,
wherein
the first organic layer and the second via insulating layer are respective portions of a same material layer, and
the second organic layer and the pixel defining layer are respective portions of a same material layer.

5. The display device of claim 1, wherein the touch protection layer includes:
a first portion covering the second touch electrode, in the display area, and
a second portion, in the sub-area.

6. The display device of claim 5, wherein
the touch protection layer includes an organic material, and
the second portion of the touch protection layer covers the first side surface and the second side surface of the organic layer, in the sub-area.

7. The display device of claim 5, further comprising:
a black matrix in the display area, on the touch sensor layer;
a color filter in the display area, on the touch sensor layer and on the black matrix; and
an organic overcoat layer including:
a first portion covering the black matrix and the color filter, in the display area, and
a second portion, in the sub-area.

8. The display device of claim 7, wherein the touch protection layer includes an inorganic material.

9. The display device of claim 8, wherein the second portion of the touch protection layer which includes the inorganic material covers the first side surface and the second side surface of the organic layer, in the sub-area.

10. The display device of claim 8, wherein the second portion of the touch protection layer covers the second side surface of the organic layer without overlapping the first side surface of the organic layer, in the sub-area.

11. The display device of claim 8, wherein the second portion of the organic overcoat layer covers the first side surface and the second side surface of the organic layer.

12. The display device of claim 1, further comprising:
a circuit board which provides a driving voltage to the pixel;
a driving voltage supply line in the sub-area, the driving voltage supply line including:
a body portion at which the driving voltage supply line is connected to the circuit board, and
branch portions branching from the body portion, and spaced apart from each other along the body portion,
wherein the opening of the organic layer is between the branch portions of the driving voltage supply line.

13. The display device of claim 1, wherein the touch inorganic insulating layer includes silicon.

14. The display device of claim 1, wherein the substrate is a flexible polymer substrate.

15. An electronic device comprising:
a display device; and
a processor which controls the display device,
wherein the display device includes:
a substrate including:
a display area including a pixel, and
a peripheral area adjacent to the display area and including a sub-area and a bending area which is between the display area and the sub-area;
an inorganic insulating layer in the display area and the peripheral area, on the substrate;
an organic layer in the display area and the peripheral area, on the inorganic insulating layer, and in which an opening is defined in the sub-area, the opening exposing the inorganic insulating layer to outside the organic layer and defined by:
a first side surface of the organic layer, and
a second side surface of the organic layer which is opposite to the first side surface and further from the bending area than the first side surface; and
a touch sensor layer on the organic layer and including:
a first touch electrode overlapping the display area;
a touch inorganic insulating layer including:
a first portion covering the first touch electrode, in the display area, and
a second portion covering the second side surface of the organic layer and not overlapping the first side surface of the organic layer, in the sub-area;
a second touch electrode in the display area, on the touch inorganic insulating layer; and
a touch protection layer covering the second touch electrode.

16. The electronic device of claim 15, wherein
an upper surface of the inorganic insulating layer is exposed to outside the organic layer by the opening, and
the touch inorganic insulating layer directly contacts the upper surface of the inorganic insulating layer and the second side surface of the organic layer, in the sub-area.

17. The electronic device of claim 15, wherein
the organic layer includes:
a first organic layer in which a first opening of the opening is defined;
the first opening exposing the inorganic insulating layer to outside the first organic layer and defined by a first-first side surface and a second-first side surface which is opposite to the first-first side surface and further from the bending area than the first-first side surface;
a second organic layer which is on the first organic layer and in which a second opening of the opening is defined, the second opening having a width smaller than a width of the first opening and overlapping the first opening; and
the second opening defined by:
a first-second side surface defining the first side surface of the organic layer, and
a second-second side surface which is opposite to the first-second side surface, further from the bending area than the first-second side surface and defines the second side surface of the organic layer, and
the touch inorganic insulating layer directly contacts the second-second side surface of the organic layer.

18. The electronic device of claim 17, wherein the display device further includes:
a first via insulating layer in the display area, on the inorganic insulating layer;
a second via insulating layer in the display area, on the first via insulating layer;
a pixel electrode on the second via insulating layer; and
a pixel defining layer in which a pixel opening is defined, the pixel opening exposing the pixel electrode to outside the pixel defining layer,
wherein
the first organic layer and the second via insulating layer are respective portions of a same material layer, and
the second organic layer and the pixel defining layer are respective portions of a same material layer.

19. The electronic device of claim 15, wherein the touch protection layer includes:
a first portion covering the second touch electrode, in the display area, and
a second portion, in the sub-area.

20. The electronic device of claim 15, wherein the touch protection layer includes an inorganic material and defines:
a first portion covering the second touch electrode, in the display area, and
a second portion which covers the second side surface of the organic layer, in the sub-area.
